(19) United States
(12) Patent Application Publication
(10) Pub. No.: US 2021/0066039 A1
(43) Pub. Date: Mar. 4, 2021

(54) SEMICONDUCTOR PROCESSING APPARATUS WITH IMPROVED UNIFORMITY

(71) Applicant: Applied Materials, Inc., Santa Clara, CA (US)

(72) Inventors: Jian LI, Fremont, CA (US); Viren KALSEKAR, Sunnyvale, CA (US); Paul BRILLHART, Pleasanton, CA (US); Juan Carlos ROCHA-ALVAREZ, San Carlos, CA (US); Vinay K. PRABHAKAR, Cupertino, CA (US)

(21) Appl. No.: 16/988,466

(22) Filed: Aug. 7, 2020

Related U.S. Application Data
(60) Provisional application No. 62/891,632, filed on Aug. 26, 2019.

(51) Int. Cl. H01J 37/32; H01L 21/67; H01L 21/683; C23C 16/505; C23C 16/458; C23C 16/46

(52) U.S. Cl. CPC H01J 37/32082; H01L 21/67103; H01L 21/6833; H01J 37/32724; H01J 2237/3323; C23C 16/4586; C23C 16/46; H01J 2237/2007; H01J 2237/3321; C23C 16/505

(57) ABSTRACT

One or more embodiments described herein generally relate to a semiconductor processing apparatus that utilizes high radio frequency (RF) power to improve uniformity. The semiconductor processing apparatus includes an RF powered primary mesh and an RF powered secondary mesh, which are disposed in a substrate supporting element. The secondary RF mesh is positioned underneath the primary RF mesh. A connection assembly is configured to electrically couple the secondary mesh to the primary mesh. RF current flowing out of the primary mesh is distributed into multiple connection junctions. As such, even at high total RF power/current, a hot spot on the primary mesh is prevented because the RF current is spread to the multiple connection junctions. Accordingly, there is less impact on substrate temperature and film non-uniformity, allowing much higher RF power to be used without causing a local hot spot on the substrate being processed.

### CROSS-REFERENCE TO RELATED APPLICATIONS

This application claims benefit of U.S. provisional patent application Ser. No. 62/891,632, filed Aug. 26, 2019, which is hereby incorporated herein by reference.

### BACKGROUND

### Field

One or more embodiments described herein generally relate to semiconductor processing apparatuses, and more particularly, to semiconductor processing apparatuses that utilize high radio frequency (RF) power to improve uniformity.

### Description of the Related Art

Semiconductor processing apparatuses typically include a process chamber that is adapted to perform various deposition, etching, or thermal processing steps on a wafer, or substrate, that is supported within a processing region of the process chamber. As semiconductor devices formed on a wafer decrease in size, the need for thermal uniformity during deposition, etching, and/or thermal processing steps greatly increase. Small variations in temperature in the wafer during processing can affect the within-wafer (WIW) uniformity of these often temperature dependent processes performed on the wafer.

Typically, semiconductor processing apparatuses include a temperature controlled wafer support that is disposed in the processing region of a wafer processing chamber. The wafer support includes a temperature controlled support plate and a shaft that is coupled to the support plate. A wafer is placed on the support plate during processing in the process chamber. The shaft is typically mounted at the center of the support plate. Inside the support plate, there is conductive mesh made of materials such as molybdenum (Mo) that distribute RF energy to a processing region of a processing chamber. The conductive mesh is typically brazed to a metal containing connection element, which is typically connected to an RF match and RF generator or ground.

As RF power provided to the conductive mesh becomes high, so does the RF current passing through the connection elements. Each brazed joint that couples the metal containing connection element to the conductive mesh has a finite resistance, which generates heat due to the RF current. As such, there is a sharp temperature increase, due to Joule heating, at the point where the conductive mesh is brazed to the metal containing connection element. The heat generated at the joint formed between the conductive mesh and the connection element creates a higher temperature region in the support plate near the joint which results in a non-uniform temperature across the supporting surface of the support plate.

Accordingly, there is a need in the art to reduce the temperature variation across the support plate within a process chamber by improving the process of delivering RF power to a conductive electrode disposed within a substrate support in a process chamber.

### SUMMARY

One or more embodiments described herein generally relate to semiconductor processing apparatuses that utilize high radio frequency (RF) power to improve uniformity.

In one embodiment, a semiconductor processing apparatus includes a thermally conductive substrate support comprising a primary mesh and a secondary mesh; a thermally conductive shaft comprising a conductive rod, wherein the conductive rod is coupled to the secondary mesh; and a connection assembly that is configured to electrically couple the secondary mesh to the primary mesh.

In another embodiment, a semiconductor processing apparatus includes a thermally conductive substrate support comprising a primary mesh and a secondary mesh, wherein the secondary mesh is spaced below the primary mesh; a thermally conductive shaft comprising a conductive rod, wherein the conductive rod is coupled to the secondary mesh by a brazing joint; and a connection assembly comprising multiple metal posts, wherein each of the multiple metal posts are configured to electrically couple the secondary mesh to the primary mesh via connection junctions.

In another embodiment, a semiconductor processing apparatus includes a thermally conductive substrate support comprising a primary mesh, a secondary mesh, and a heating element, wherein the secondary mesh is spaced below the primary mesh; a thermally conductive shaft comprising a conductive rod, wherein the conductive rod is coupled to the secondary mesh by a brazing joint; a connection assembly comprising multiple metal posts, wherein each of the multiple metal posts are configured to electrically couple the secondary mesh to the primary mesh and are physically coupled to each end of the secondary mesh via connection junctions; a radio frequency (RF) power source configured to distribute RF power to the secondary mesh and the primary mesh; and an alternating current (AC) power source configured to distribute AC power to the heating element.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a side cross-sectional view of a processing chamber according to embodiments of the present disclosure;

FIG. 2A a side cross-sectional view of the semiconductor processing apparatus of FIG. 1;

FIG. 2B is a schematic illustration of a temperature profile measured along a surface of a substrate in the prior art;

FIG. 2C is a schematic illustration of a temperature profile measured along a surface of a substrate according to embodiments of the present disclosure; and

FIG. 2D is a perspective view of the semiconductor processing apparatus as shown in FIG. 1.

### DETAILED DESCRIPTION

In the following description, numerous specific details are set forth to provide a more thorough understanding of the embodiments of the present disclosure. However, it will be apparent to one of skill in the art that one or more of the embodiments of the present disclosure may be practiced without one or more of these specific details. In other instances, well-known features have not been described in order to avoid obscuring one or more of the embodiments of the present disclosure.

One or more embodiments described herein generally relate to semiconductor processing apparatuses that utilize high radio frequency (RF) power to improve uniformity. In these embodiments, a semiconductor processing apparatus includes an RF powered primary mesh and an RF powered secondary mesh, which are disposed in a substrate supporting element. The secondary RF mesh is placed underneath the primary RF mesh at a certain distance. A connection assembly is configured to electrically couple the secondary mesh to the primary mesh. In some embodiments, the connection assembly includes multiple metal posts. RF current flowing out of the primary mesh is distributed into multiple connection junctions. As such, even at high total RF power/current, a hot spot on the primary mesh is prevented because the RF current is spread to the multiple connection junctions.

Additionally, a single RF conductive rod is brazed onto the secondary mesh. Therefore, although there is a hot spot at the brazing joint, the hot spot at the brazing joint is much farther away from the substrate supporting surface compared to conventional designs. Accordingly, embodiments described herein advantageously have less impact on substrate temperature and film non-uniformity and allow much higher RF power to be used without causing a local hot spot on the substrate being processed.

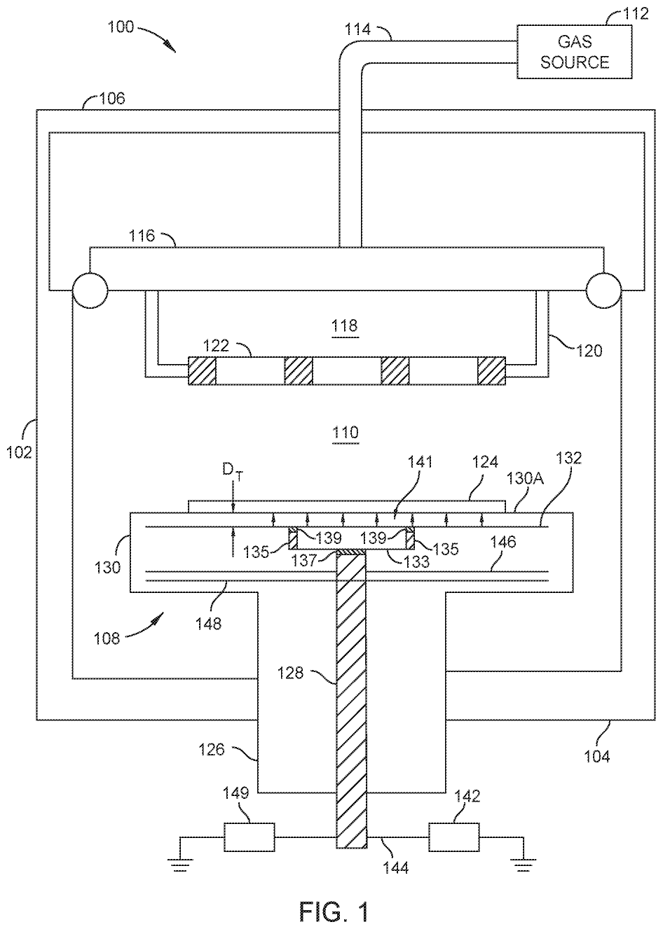

FIG. 1 is a side cross-sectional view of a processing chamber 100 according to embodiments of the present disclosure. By way of example, the embodiment of the processing chamber 100 in FIG. 1 is described in terms of a plasma-enhanced chemical vapor deposition (PECVD) system, but any other type of wafer processing chamber may be used, including other plasma deposition, plasma etching, or similar plasma processing chambers, without deviating from the basic scope of disclosed provided herein. The processing chamber 100 may include walls 102, a bottom 104, and a chamber lid 106 that together enclose a semiconductor processing apparatus 108 and a processing region 110. The semiconductor processing apparatus 108 is generally a substrate supporting element that may include a pedestal heater used for wafer processing. The pedestal heater may be formed from a dielectric material, such as a ceramic material (e.g., AlN, BN, or Al₂O₃ material). The walls 102 and bottom 104 may comprise an electrically and thermally conductive material, such as aluminum or stainless steel.

The processing chamber 100 may further include a gas source 112. The gas source 112 may be coupled to the processing chamber 100 via a gas tube 114 that passes through the chamber lid 106. The gas tube 114 may be coupled to a backing plate 116 to permit processing gas to pass through the backing plate 116 and enter a plenum 118 formed between the backing plate 116 and gas distribution showerhead 122. The gas distribution showerhead 122 may be held in place adjacent to the backing plate 116 by a suspension 120, so that the gas distribution showerhead 122, the backing plate 116, and the suspension 120 together form an assembly sometimes referred to as a showerhead assembly. During operation, process gas introduced into the processing chamber 100 from the gas source 112 can fill the plenum 118 and pass through the gas distribution showerhead 122 to uniformly enter the processing region 110. In alternative embodiments, process gas may be introduced into the processing region 110 via inlets and/or nozzles (not shown) that are attached to one or more of the walls 102 in addition to or in lieu of the gas distribution showerhead 122.

The processing chamber 100 further includes an RF generator 142 that may be coupled to the semiconductor processing apparatus 108. In embodiments described herein, the semiconductor processing apparatus 108 includes a thermally conductive substrate support 130. A primary mesh 132 and a secondary mesh 133 are embedded within the thermally conductive substrate support 130. In some embodiments, the secondary mesh 133 is spaced a distance below the primary mesh 132. The substrate support 130 also includes an electrically conductive rod 128 disposed within at least a portion of a conductive shaft 126 that is coupled to the substrate support 130. A substrate 124 (or wafer) may be positioned on a substrate supporting surface 130A of the substrate support 130 during processing. In some embodiments, the RF generator 142 may be coupled to the conductive rod 128 via one or more transmission lines 144 (one shown). In at least one embodiment, the RF generator 142 may provide an RF current at a frequency of between about 200 kHz and about 81 MHz, such as between about 13.56 MHz and about 40 MHz. The power generated by the RF generator 142 acts to energize (or “excite”) the gas in the processing region 110 into a plasma state to, for example, form a layer on the surface of the substrate 124 during a plasma deposition process.

A connection assembly 141 is configured to electrically couple the secondary mesh 133 to the primary mesh 132. In some embodiments, the connection assembly 141 includes multiple metal posts 135. The multiple metal posts 135 can be made of nickel (Ni), a Ni containing alloy, molybdenum (Mo), tungsten (W), or other similar materials. RF current flowing out of the primary mesh 132 is distributed into multiple connection junctions 139. As such, even at high total RF power/current, a hot spot on the primary mesh 132 is prevented because the RF current is spread to the multiple connection junctions 139. In some embodiments, each of the multiple metal posts 135 are configured to electrically couple the secondary mesh 133 to the primary mesh 132 and are physically coupled to the ends or about the perimeter of the secondary mesh 133. Additionally, the conductive rod 128 is brazed onto the secondary mesh 133 at a brazing joint 137. Therefore, although there is a hot spot at the brazing joint 137, the hot spot at the brazing joint 137 is much farther away from the substrate supporting surface 130A compared to conventional designs. Accordingly, embodiments described herein advantageously have less impact on the substrate 124 temperature and film non-uniformity and allow much higher RF power to be used without causing a local hot spot on the substrate 124.

Embedded within the substrate support 130 is the primary mesh 132, the secondary mesh 133, and a heating element 148. The biasing electrode 146, which is optionally formed within the substrate support 130, can act to separately provide an RF “bias” to the substrate 124 and processing region 110 through a separate RF connection (not shown). The heating element 148 may include one or more resistive heating elements that are configured to provide heat to the substrate 124 during processing by the delivery of AC power by an AC power source 149. The biasing electrode 146 and heating element 148 can be made of conductive materials such as Mo, W, or other similar materials.

The primary mesh 132 can also act as an electrostatic chucking electrode, which helps to provide a proper holding force to the substrate 124 against the supporting surface 130A of the substrate support 130 during processing. As noted above, the primary mesh 132 can be made of a refractory metal, such as molybdenum (Mo), tungsten (W), or other similar materials. In some embodiments, the primary mesh 132 is embedded at a distance DT (See FIG. 1) from the supporting surface 130A, on which the substrate 124 sits. The DT may be very small, such as 1 mm or less. Therefore, variations in temperature across the primary mesh 132 greatly influence the variations in temperature of the substrate 124 disposed on the supporting surface 130A. The heat transferred from the primary mesh 132 to the supporting surface 130A is represented by the H arrows in FIG. 1.

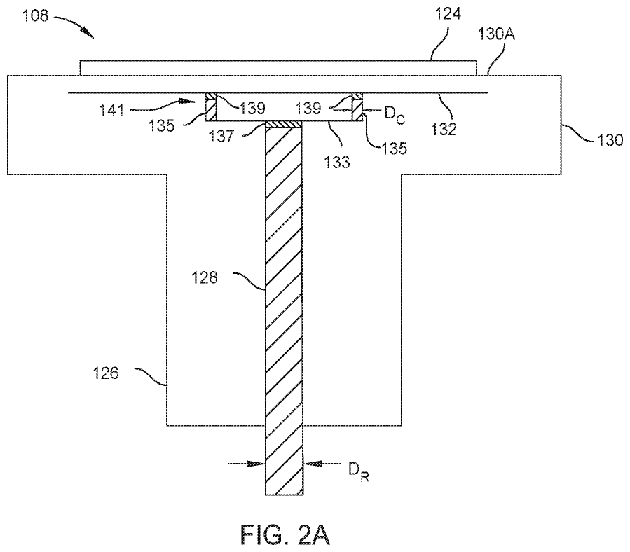

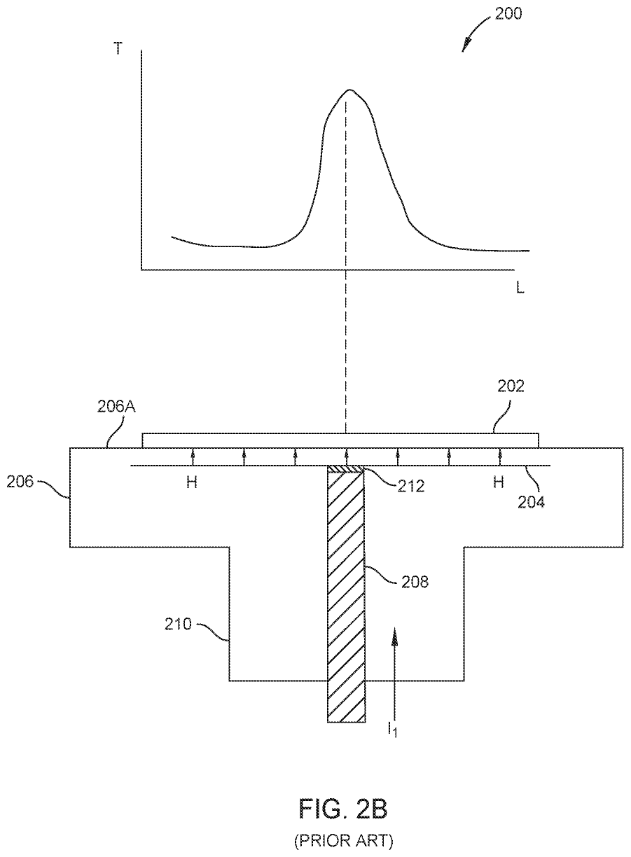

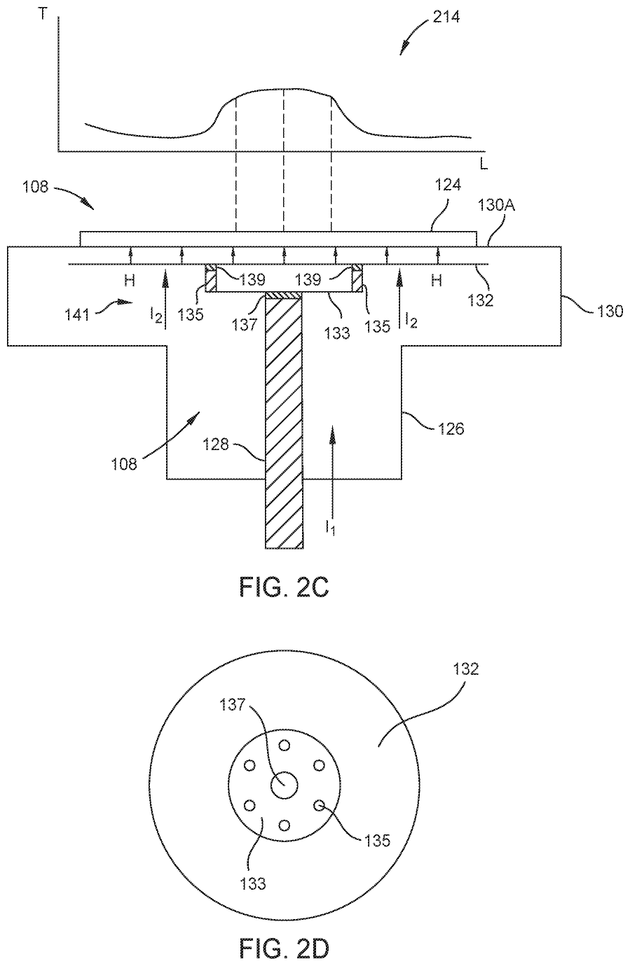

Therefore, by dividing, distributing, and spreading out the amount of RF current provided by each of the metal posts 135 from the secondary mesh 133 to the primary mesh 132, the added temperature increase created at the metal posts 135 to the connection junctions 139 is minimized. Minimizing the temperature increase results in a more uniform temperature across the primary mesh 132 versus conventional connection techniques, which are discussed further below in conjunction with FIG. 2B. A more uniform temperature across the primary mesh 132, due to the use of the connection assembly 141 described herein, creates a more uniform temperature across the supporting surface 130A and substrate 124. Additionally, the conductive rod 128 is brazed onto the secondary mesh 133 at the brazing joint 137. Therefore, although there is a hot spot at the brazing joint 137, the hot spot at the brazing joint 137 is much farther away from the substrate supporting surface 130A compared to conventional designs. Accordingly, embodiments described herein advantageously have less impact on the substrate 124 temperature and film non-uniformity and allow much higher RF power to be used without causing a local hot spot on the substrate 124.

FIG. 2A a side cross-sectional view of the semiconductor processing apparatus 108 of FIG. 1. In these embodiments, the connection element 141 disclosed herein also provides an advantage over conventional designs because the diameter of the metal posts 135, represented by Dc in FIG. 2A, is smaller than the diameter of the conductive rod 128, represented by DR in FIG. 2A. Due to the smaller diameter of Dc, each of the metal posts 135 have smaller cross-sectional areas and thus a smaller contact area at each of the connection junctions 139 than the larger cross-sectional area of the conductive rod 128 and contact area at the brazing joint 137, but all together and in totality, the cross-sectional areas of the plurality of metal posts 135 is equal to or greater than the cross-sectional area of the conductive rod 128. In one embodiment, the cross-sectional area of the metal posts 135 is the same or larger than the cross-sectional area of the conductive rod 128, as long as the totality of the cross-sectional areas of the plurality of metal posts 135 is greater than the cross-sectional area of the conductive rod 128. As described further below, the same RF current is split into the plurality of metal posts 135. As such, the RF current through each metal post 135 is only a fraction of the total RF current generating much less heat in each of the metal posts 135 and at the connection junctions 139. Because the thermal conductivity of each of the metal posts 135 is the same as the conductivity of the conductive rod 128, as they are made from the same material, due to the plurality of metal posts 135, less heat is generated for each metal post 135 and is spread out more evenly across metal posts 135. This arrangement provides the heat more uniformly within the substrate support 130, helping to create a more uniform temperature distribution across the supporting surface 130A and substrate 124.

In an effort to illustrate the effect of using the conductive assembly configurations disclosed herein, FIG. 2B is provided as a schematic illustration of a temperature profile formed across a prior art substrate supporting surface 206A and a substrate 202 of a prior art substrate support 206 in the prior art, and FIG. 2C is provided as a schematic illustration of the temperature profile formed across the supporting surface 130A and the substrate 124 according to one or more embodiments of the present disclosure. As shown in FIG. 2B, a RF current is transferred through the prior art conductive rod 208. This RF current is represented by the value I₁. The prior art conductive rod 208 is disposed within the prior art conductive shaft 210 and is connected directly to the prior art mesh 204 at a single prior art junction 212. Therefore, the current flows entirely from the prior art conductive rod 208 to the single prior art junction 212. Conductive rods have a finite electrical impedance, which generates heat due to the delivery of the RF current through the prior art conductive rod 208. As such, there is sharp increase in heat provided to the prior art connection junction 212 due to the reduced surface area that is able to conduct the RF power. As the heat flows upward through the prior art conductive substrate support 206 to the substrate 202, as shown by the H arrows, the temperature at the location of the substrate 202 above the prior art junction 212 spikes in the center region as shown by the graph 200, resulting in a non-uniform film layer.

Contrarily, as shown in FIG. 2C, embodiments described herein provide the advantage of spreading the current I₁ generated through the conductive rod 128 into each of the metal posts 135. The current through each of the metal posts 135 is represented by I₂. In some embodiments, the current I₂ through each of the metal posts 135 can be equal. Therefore, in at least one embodiment, the metal posts 135 can comprise two elements (shown here). However, the metal posts 135 can comprise any number of multiple elements, including three or more. The current I₂ through the metal posts 135 can be at least two times less than the current I₁ through the conductive rod 128. Accordingly, current I₂ flows into the connection junctions 139 at a lower magnitude and at multiple distributed out points across the primary mesh 132, helping spread the amount of heat generated across the substrate 124, creating much less of a heat increase at any one point, as shown by the graph 214. This acts to improve the uniformity in the film layer. The spread of the metal posts 135 across the primary mesh 132 of the substrate support 130 is best shown in FIG. 2D, which provides a perspective view of one embodiment the semiconductor processing apparatus 108. As shown, each of the metal posts 135 can be spread relatively far apart from each other, widely distributing the current and the generated heat across the supporting surface 130A, resulting in a uniform heat spread across the substrate 124.

While the foregoing is directed to implementations of the present invention, other and further implementations of the invention may be devised without departing from the basic scope thereof, and the scope thereof is determined by the claims that follow.

We claim:

1. A semiconductor processing apparatus, comprising:
a thermally conductive substrate support comprising a primary mesh and a secondary mesh;
a thermally conductive shaft comprising a conductive rod, wherein the conductive rod is coupled to the secondary mesh; and
a connection assembly that is configured to electrically couple the secondary mesh to the primary mesh.

2. The semiconductor processing apparatus of claim 1, further comprising a RF generator that is coupled to the conductive rod.

3. The semiconductor processing apparatus of claim 2, wherein a current generated by the RF generator is spread from the secondary mesh to the primary mesh.

4. The semiconductor processing apparatus of claim 1, wherein the primary mesh is configured to act as an electrostatic chucking electrode.

5. A semiconductor processing apparatus, comprising:
a thermally conductive substrate support comprising a primary mesh and a secondary mesh, wherein the secondary mesh is spaced below the primary mesh;
a thermally conductive shaft comprising a conductive rod, wherein the conductive rod is coupled to the secondary mesh by a brazing joint; and
a connection assembly comprising multiple metal posts, wherein each of the multiple metal posts are configured to electrically couple the secondary mesh to the primary mesh via connection junctions.

6. The semiconductor processing apparatus of claim 5, wherein a diameter of each of the multiple metal posts is less than a diameter of the conductive rod.

7. The semiconductor processing apparatus of claim 6, wherein each of the metal posts have smaller cross-sectional areas than a cross-sectional area of the conductive rod.

8. The semiconductor processing apparatus of claim 7, wherein the connection junctions have a smaller contact area than the brazing joint.

9. The semiconductor processing apparatus of claim 5, further comprising a RF generator that is coupled to the conductive rod.

10. The semiconductor processing apparatus of claim 9, wherein a current generated by the RF generator is spread equally through each of the multiple metal posts.

11. The semiconductor processing apparatus of claim 10, wherein the current through each of the multiple metal posts is at least two times less than the current generated by the RF generator.

12. The semiconductor processing apparatus of claim 5, wherein the multiple metal posts comprise at least two metal posts.

13. The semiconductor processing apparatus of claim 5, wherein the multiple metal posts are made of Ni.

14. A semiconductor processing apparatus, comprising:
a thermally conductive substrate support comprising a primary mesh, a secondary mesh, and a heating element, wherein the secondary mesh is spaced below the primary mesh;
a thermally conductive shaft comprising a conductive rod, wherein the conductive rod is coupled to the secondary mesh by a brazing joint;
a connection assembly comprising multiple metal posts, wherein each of the multiple metal posts is configured to electrically couple the secondary mesh to the primary mesh and is physically coupled to the secondary mesh via a connection junction;
a radio frequency (RF) power source configured to distribute RF power to the secondary mesh and the primary mesh; and
an alternating current (AC) power source configured to distribute AC power to the heating element.

15. The semiconductor processing apparatus of claim 14, further comprising a RF generator that is coupled to the conductive rod.

16. The semiconductor processing apparatus of claim 15, wherein a current generated by the RF generator is spread equally through each of the multiple metal posts.

17. The semiconductor processing apparatus of claim 16, wherein the current through each of the multiple metal posts is at least two times less than the current generated by the RF generator.

18. The semiconductor processing apparatus of claim 14, wherein the multiple metal posts comprise at least two metal posts.

19. The semiconductor processing apparatus of claim 14, wherein the multiple metal posts are made of Mo.

20. The semiconductor processing apparatus of claim 14, wherein the primary mesh is configured to act as an electrostatic chucking electrode.
